(19) United States
(12) Patent Application Publication
(10) Pub. No.: US 2023/0216164 A1
(43) Pub. Date: Jul. 6, 2023

(54) POROUS DIELECTRIC MATERIAL

(71) Applicant: Oulun yliopisto, Oulu (FI)

(72) Inventors: Heli JANTUNEN, Oulu (FI); Krisztian KORDAS, Oulu (FI); Henrikki LIIMATAINEN, Oulu (FI); Sami MYLLYMÄKI, Oulu (FI); Mikko NELO, Oulu (FI); Petra PALVÖLGYI, Oulu (FI); Olli PITKÄNEN, Oulu (FI)

(21) Appl. No.: 17/566,594

(22) Filed: Dec. 30, 2021

(51) Int. Cl. H01P 1/20; H01P 11/00; C23C 18/12; C23C 14/18; C23C 14/34; C23C 14/04; C23C 28/00

(52) U.S. Cl. CPC H01P 1/2002; C23C 14/34; C23C 14/042; C23C 14/185; C23C 18/1204; C23C 18/1245; C23C 18/1254; C23C 28/322; H01P 11/007

(57) ABSTRACT

The current invention describes a method of manufacturing a porous dielectric material, the method comprising (a) providing a porous template, (b) coating the porous template with an inorganic dielectric material or a precursor of an inorganic dielectric material to form a coated porous template, (c) treating the coated porous template to remove the porous template and to form a porous structure of dielectric material from the coating of inorganic dielectric material or precursor of an inorganic dielectric material, and (d) combining the formed porous structure of dielectric material with a coating polymer to form the porous dielectric material. The invention also relates to RF components on a substrate material, with a conductive material deposited on a porous dielectric material.

### FIELD OF THE INVENTION

The invention relates to porous materials in general and in particular to porous materials useful as dielectric materials.

### BACKGROUND OF THE INVENTION

Porous materials have been studied for various applications. Several mature technologies exist for producing porous dielectric materials that have been exploited in chemistry, biomedical, sensor, environmental and optical applications. One interesting application for investigating porous materials is radio frequency components. Modern communication systems transit to higher frequency ranges (from Gigahertz to even Terahertz ranges) which demands new requirements for the radio frequency components.

Signal distortion, noise and power consumption of radio frequency (RF) devices are determined by the wave propagation delay and attenuation, which among others depend on the relative permittivity (εᵣ) and loss factor (tan δ), and thus minimizing those is one of the keys for enabling or improving RF device performance. Polymers can offer relatively low εᵣ but usually have high tan δ. On the contrary, ceramics have intrinsically higher εᵣ and very moderate tan δ, however both are influenced by the microstructure and porosity (or density) of the material.

There is therefore a need to develop novel materials with both low relative permittivity (εᵣ) and loss factor (tan δ).

### BRIEF SUMMARY OF THE INVENTION

An aspect of the present invention is thus to provide a method and a material to solve the above problems. The aspects of the invention are achieved by a method, process and material characterized by what is stated in the independent claims. The embodiments of the invention are disclosed in the dependent claims.

Thereby, an aspect of the present invention is to provide a method of manufacturing a porous dielectric material, the method comprising:
(a) providing a porous template,
(b) coating the porous template with an inorganic dielectric material or a precursor to an inorganic dielectric material to form a coated porous template,
(c) treating the coated porous template to remove the porous template and to form a porous structure of dielectric material from the coating of inorganic dielectric material or precursor to an inorganic dielectric material, and
(d) combining the formed porous structure of dielectric material with a coating polymer to form a porous dielectric material.

### BRIEF DESCRIPTION OF THE DRAWINGS

FIGS. 1A and 1B are schematic figures of examples of the substrate material, which can be formed by the methods hereby described. FIG. 1A shows a perspective and a cross-sectional drawing of the substrate, showing the various layers. FIG. 1B shows in detail the nanocelluse film, with which the silica foam (porous structure of dielectric material).

FIG. 2 shows how a silica-cellulose nanocomposite (porous dielectric material) is formed.

FIG. 3 is a schematic flow-sheet of the method according to the invention.

### DETAILED DESCRIPTION OF THE INVENTION

The following embodiments are examples. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments. Furthermore, words “comprising” and “including” should be understood as not limiting the described embodiments to consist of only those features that have been mentioned and such embodiments may contain also features/structures that have not been specifically mentioned.

In one aspect, the current invention relates to a method of manufacturing a porous dielectric material. The method comprises providing a porous template. The material of the porous template can be any soft or hard substance (referred in the scientific literature as soft or hard template, respectively) that can be removed after coating the skeleton of the porous template with the functional material of interest (as described later in detail in this disclosure). The porous template is sacrificial, which means it will later be removed.

The method therefore further comprises coating the porous template with an inorganic dielectric material or a precursor of an inorganic dielectric material. This coating forms a coated porous template. The coated porous template is then treated to remove the porous template and to form a porous structure of dielectric material from the coating of inorganic dielectric material or precursor to an inorganic dielectric material. In one embodiment of the current invention treating the coated porous template to remove the porous template is performed by annealing the coated porous template in air or oxygen environment, which removes the porous template.

Removal of the porous template can also be achieved e.g. by dissolution, chemical etching or by oxidation (burning) depending on the materials of the template. In one embodiment of the current invention, a porous polymer (such as melamine) is used as template that can be removed either by direct oxidation or by carbonizing the polymer first to form a self-similar porous carbon template, and then burning that off in a subsequent step.

In a one embodiment a carbon skeleton is used as the template in the current invention. When a polymer is pyrolyzed either to form the carbon skeleton template or the be removed, leaving the coating to form the structure, the size of the template can vary. For example, melamine foam polymer template may shrink up to about 50% linearly when pyrolyzed to form a carbon skeleton template.

On the other hand, it can be advantageous to use a polymer porous template, which is coated and followed by a treatment to remove the polymer porous template, the treatment can be annealing or an oxidation (burning) step. This approach is more direct and easier to be performed, since there is no need for the initial pyrolysis to form the carbon skeleton template. Furthermore, the template can be made of porous metals, alloys or any inorganic material but their removal after forming the dielectric layer on them shall be made accordingly (e.g. by chemical etching using corresponding chemistries known from the literature).

The method of manufacturing a porous composite material further comprises a step of coating the porous template with an inorganic dielectric material or a precursor of an inorganic dielectric material to form a coated porous template. The porous template forms the structural support on which the dielectric material or its precursor is coated. The coating must be complete and may be repeated to ensure the surface of the porous template is completely coated if necessary.

The coating of the template can be performed by wet chemical methods (e.g. sol-gel synthesis, precipitation, growth or alike) but can be also done by chemical vapour deposition or by atomic layer deposition.

The coating of the porous template is done with a dielectric material or a precursor of dielectric material. Any suitable dielectric material can be used. The dielectric material can be selected from silica, alumina, magnesia and boron nitride. Non-stoichiometric oxides, oxyhydroxides, oxyfluorides, nitrides or oxynitrides of B, Si, Al and Mg may be applied too.

The method of manufacturing a porous dielectric material further comprises a step of removing the porous template. This removal can be performed by annealing, dissolution, etching or oxidation (burning) of the coated porous template to remove the template and to form a porous structure of dielectric material from the coating of inorganic dielectric material or precursor of an inorganic dielectric material. Removing the template by annealing, dissolution, etching or oxidation (burning) leaves the coating to form the porous functional structure.

The conditions for the removal of the porous sacrificial template need to be chosen such to make sure the template is removed as completely as possible. The exact conditions of the removal therefore depend at least on which type of template is used, the size of the template and equipment used in the process. When the porous template is a carbon skeleton, e.g. formed by pyrolyzing a melamine foam polymer, oxidation (burning) or annealing to remove the template, can be performed at a temperature above 700° C. for an extended period of time of at least 60 min, e.g. 2 h at about 800° C.

When the coating is done with a precursor of dielectric material, it is preferred that simultaneously with burning off the template also the precursor coating transforms to the final dielectric material.

Removing the template leaves the coating to form a structure of dielectric material. The structure of dielectric material formed by the above-described method is highly porous and fragile. The structure of dielectric material can now be used as basis for depositing a conductive material on at least one side of the dielectric material.

Depositing conductive material on at least one side of the dielectric material can be done in two different ways, either by applying a conductive material or its micropattern directly on the surface of the dielectric material (e.g. by any physical vapor deposition method combined with masking), or by applying a sheet of coating polymer, which coating polymer can be biopolymer or synthetic polymer, on the dielectric material before depositing a conductive material on the sheet of coating polymer. The choice of depositing conductive material can depend on the size of the surface pores and on the desired quality (e.g. resolution, line definition, thickness) of the conductive pattern.

When the size of the surface pores is small not to influence the desired resolution (line definition) of the conductive material or its micropattern, direct deposition of the conductive material on the surface is favored. For instance, at 1-100 GHz, surface voids with an approximate respective dimeter of 2.0-0.2 µm are not influencing the device performance, thus direct metallization on the surface shall be sufficient. On the other hand, if the pores on the surface would compromise the desired quality (e.g. resolution, line definition, thickness), a sheet of biopolymer or synthetic polymer on at least one side of the dielectric material is to be applied, on which the conductive material is meant to be deposited. The sheet of biopolymer or synthetic polymer functions as a continuous cover of the porous dielectric material and as holder of the conductive material. Such a continuous cover means that the surface is mostly free from voids larger than about 1 µm.

The sheet of biopolymer or synthetic polymer, such as nanocellulose, can be formed by combining the dielectric material with the biopolymer or synthetic polymer. The term “nanocellulose” can hear mean any cellulose with nanofibers or microfibrillated cellulose. The combination can be done, e.g. by dip-coating, printing, or spraying the dispersion of biopolymer or synthetic polymer to coat the surface of the dielectric material on at least one side of the porous material. In one embodiment of the current invention, the sheet is formed from nanocellulose by dipping the porous dielectric in nanocellulose dispersions as described in the experimental section titled “Production of silica foam with cellulose sheet coatings”.

In another embodiment the invention relates to substrate material, wherein the substrate material comprises
a support of porous dielectric material, which is formed by coating a porous template with the dielectric material or a pre-cursor of dielectric material, and removing the porous template after coating,
optionally a sheet of biopolymer or synthetic polymer on at least on side of the support of porous dielectric material, and
a conductive material deposited on at least one side of the support of porous dielectric material.

The substrate material according to the invention have a conductive material deposited on at least one side and if the substrate material also comprises a sheet of polymer, the conductive material is deposited on the sheet of polymer. The purpose of the sheet of polymer is to form a smooth envelope surface on the support of porous dielectric material where the conductive material can be deposited. The substrate material can be formed using any of the method herein describe. The materials and other details of the substrate material can also be as described in the methods disclosed.

Radio frequency filters are used in mobile telecommunication systems to reduce interference of adjacent bands and to avoid out-of-band spurious signals of transceivers, thus ensuring optimum radio performance. Meta-surface band pass filters are physically located in the close proximity of the transceiver, where the signal is propagating in the free space. Accordingly, substrates with ultimately low εᵣ and tan δ are required and the pattern definition of the conductive metamaterial structures shall be of high quality to ensure low insertion loss, low ripple, and high stop-band attenuation in the filter. As the highly porous nanocellulose coated silica foams described herein suggest ideal dielectric properties for substrates of such a metamaterial surface structure based planar filter, arrays of double split-ring-resonators (DSRRs) composed of two concentric metallic rings with opposite splits can be designed on the basis of such a substrate. The DSRR element is coupled to a magnetic field component of the propagating wave oscillating in the axial direction and establishing a current flow that induces a magnetic dipole parallel or antiparallel to the magnetic field.

Periodic arrays of DSRRs may be produced with good repeatability and throughput on the porous surfaces by sputtering silver through a shadow mask according to optical microscopy analysis. Because of the good accuracy of the line width definition (±10% within the actual patterns, and ±5% between filter samples) the transmittance spectra of several DSRR filter structures measured at 100-500 GHz are nearly identical and the measured pass band at 240-300 GHz with a transmittance of 90% show very good match with the corresponding simulation data (240-310 GHz and 95%). It is worth mentioning that the variations of permittivity values of the substrates used are expected to cause only very minor changes (1%) in the transmittance response. Furthermore, the transmittance spectra of the filters measured at a sample position rotated with 90 degree compared to the first set of measurements shows a narrowed pass band and 270-300 GHz and broadened stop band at lower frequencies (210-260 GHz). The difference of the transmission spectra between the original and 90° rotated positions is plausible considering the symmetry of the DSRR structures, and such characteristics could actually be beneficial in radio systems utilizing polarized waves.

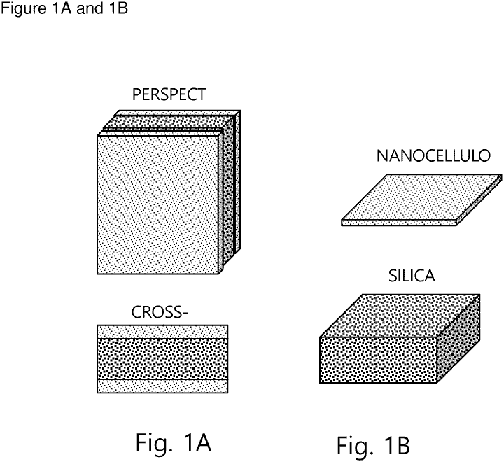

FIGS. 1A and 1B are schematic figures of examples of the substrate material, which can be formed by the methods hereby described. FIG. 1A shows a perspective and a cross-sectional drawing of the substrate, showing the various layers. FIG. 1B shows in detail the nanocelluse film, with which the silica foam (porous structure of dielectric material).

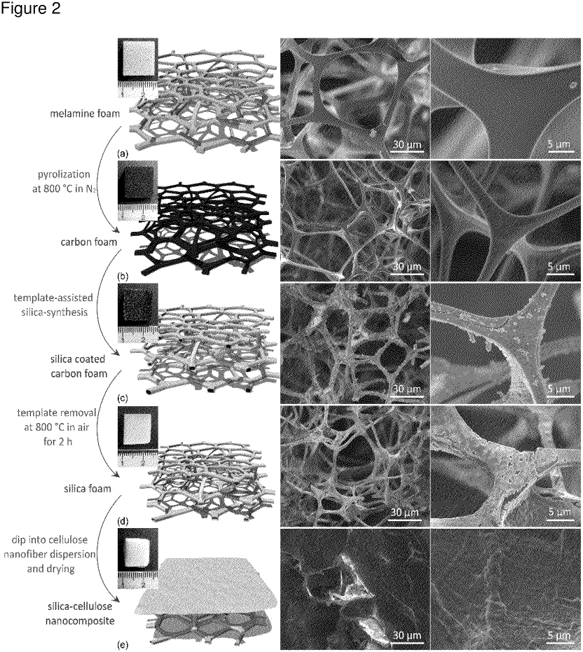

FIG. 2 shows an embodiment of the method according to the invention, where the porous dielectric material is formed.

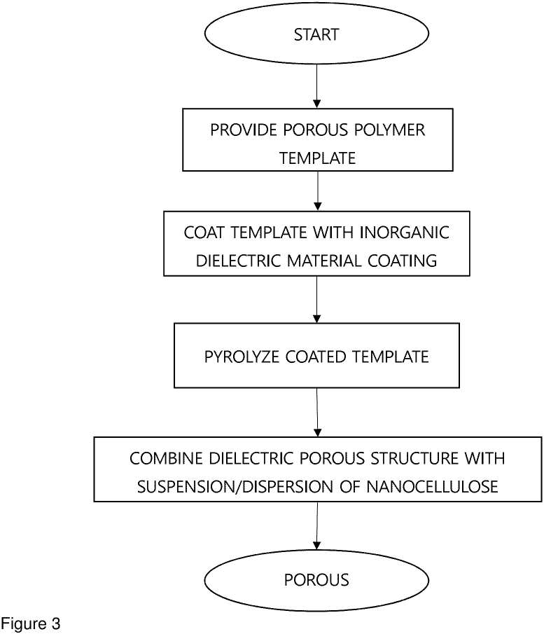

FIG. 3 shows a schematic flow-sheet of the method according to the invention.

### Example

### Production of Silica Foam With Cellulose Sheet Coatings

First, the carbon foam was prepared by a pyrolysis of the melamine foam in a 4″ quartz tube furnace under N₂ flow (150 mL/min). The furnace was heated to 300° C. at a rate of 15° C./min, then to 800° C. at a rate of 2° C./min, and kept there for 60 min. Next a thin silica shell was synthesized on the carbon skeleton by base catalyzed sol-gel polycondensation of the TEOS. The carbon foams were cut to a size of about 15×15×3 mm³ and placed in a mixture of 26 mL EtOH and 3 mL of NH₄OH. After 5 min, 2 mL TEOS was added, and the carbon foam was kept in the reaction mixture for 2 h at 23° C. The silica coated foam products were washed with EtOH and dried for 2 h in an oven at 50° C. To make sure silica is completely coating the carbon skeleton, the sol-gel process was repeated two times, after which the samples were pyrolyzed (annealed) in a tube furnace at 800° C. in air for 2 h to burn off the carbon skeleton and simultaneously to calcine the silica gel.

To provide a smooth envelope of the silica foam, the foams were immersed into the cellulose nanofiber (0.1 wt.%) suspension and removed at once, the foams were then placed between two release foils and aluminum plates to preserve the straightness of the immersed sides during the drying, then put in box furnace, heated to 105° C. and left there for 2 h. In this manner, a sandwich structure was created where the silica-coated skeleton was provided between two layers of cellulose nanofiber layers.

### Depositing Conductive Material on Cellulose Coated Silica Foam

Arrays of planar double split-ring resonators and Fresnel zone plate lenses were designed, and respective patterns were sputtered (silver, 500 nm, deposition conditions: 95 W, 1.5 Å/s deposition rate, Ar atmosphere, p=2.4 mTorr) on the cellulose coated silica foam through the corresponding laser-cut shadow mask.

### Results (Silica-Foam)

Highly porous silica foam was thus obtained by the sol-gel synthesis on sacrificial carbon foam template, prepared by pyrolization of melamine foam. During the carbonization, melamine foam shrank about 10% in volume and changed its color from pale gray to black. The resulting carbon foam remained elastic and kept the original skeletal structure. After the carbonization process, a thin continuous silica shell was deposited on the skeleton by a base catalyzed sol-gel polymerization of the silica precursor. Light weight silica foams (ρ = 0.026 ± 0.001 g/cm3 and porosity of 98.9 ± 0.1% according to gravimetric analysis) having interconnected hollow skeletal nanotubes in their structure were obtained by pyrolyzing (annealing) the gel coated carbon foam at 800° C. in air for 2 h, which resulted in a simultaneous burning off of the carbonaceous core and calcination of the silica gel. In the course of the calcination process, the volume of the silica foam became about 35% smaller in reference to the gel coated carbon foam. The pore structures of the silica foam and the nanocellulose film envelopes are clearly visible in constructed three-dimensional models obtainable by high resolution computed tomography.

Calculations based on the µ-CT data give porosity being higher than 90%. It is important to mention that this value is underestimated, since pores below 4.5 µm³ (e.g. the cavities in the silica skeleton at the places of the sacrificial carbon skeleton template, what was burned off) are undetectable with this technique and measurement parameters. Since the pores in the silica foam are having too large size (diameter of ~30 µm) to deposit micropatterns of any planar metal thin films on the surface, the silica foams were coated with the thin envelope film of cellulose nanofibers. This was achieved by immersing the silica foam samples into the cellulose nanofiber suspension from which the nanofibers sediment and clog the voids on the surface forming a thin continuous film, which after drying, is suitable for post metallization. The density of the obtained silica-cellulose composite is ρ = 0.025 ± 0.005 g/cm³, calculated from dimension and mass measurements with a corresponding composition of 78.8 ± 3.7 wt.% silica and 21.2 ± 3.7 wt.% cellulose.

### Results (Dielectric Permittivity and Loss Factor)

The dielectric permittivity of the foams measured up to 2 THz is extremely low (εᵣ = 1.018 ± 0.003 at 300 GHz, and similar in the entire frequency window), nearly close to that of air. The value of deduced loss factor is also extremelylow, practically within the error of the measurement (tan δ < 3×10⁻⁴ at 300 GHz). These results are plausible considering the very high porosity of the samples. According to the Maxwell-Garnett effective medium approximation model, the relative dielectric permittivity calculated from the permittivity values and filling factors of the components of the composite is εᵣ = 1.016, which is in great agreement with the experimental data.

It will be obvious to a person skilled in the art that, as the technology advances, the inventive concept can be implemented in various ways. The invention and its embodiments are not limited to the examples described above but may vary within the scope of the claims.

1. A method of manufacturing a porous dielectric material, the method comprising:
(a) providing a porous template,
(b) coating the porous template with an inorganic dielectric material or a pre-cursor to an inorganic dielectric material to form a coated porous template,
(c) treating the coated porous template to remove the porous template and to form a porous structure of dielectric material from the coating of inorganic dielectric material or pre-cursor to an inorganic dielectric material, and
(d) combining the formed porous structure of dielectric material with a coating polymer to form the porous dielectric material.

2. The method according to claim 1, wherein treating the coated porous template to remove the porous template comprises annealing the coated porous template in oxygen or air.

3. The method according to claim 2, wherein the annealing is performed at a temperature above 700° C. for at least 60 minutes.

4. The method according to claim 1, wherein the porous template is a polymer template or a carbon skeleton template.

5. The method according to claim 4, wherein the porous template is a carbon skeleton template, and the carbon skeleton template is formed by pyrolyzing a polymer foam template.

6. The method according to claim 4, wherein the polymer foam template is a melamine foam template.

7. The method according to claim 2, wherein the porous template is a polymer template or a carbon skeleton template.

8. The method according to claim 7, wherein the porous template is a carbon skeleton template, and the carbon skeleton template is formed by pyrolyzing a polymer foam template.

9. The method according to claim 8, wherein the polymer foam template is a melamine foam template.

10. The method according to claim 1, wherein the combining in (d) is performed such that the coating polymer forms a sheet on at least one side of the formed porous structure of dielectric material.

11. The method according to claim 1, wherein the coating polymer is a biopolymer or a synthetic polymer.

12. The method according to claim 11, wherein the coating polymer is a nanocellulose biopolymer.

13. The method according to claim 10, further comprising depositing conductive material either as a film or a micropattern on the sheet of coating polymer.

14. The method according to claim 1, wherein the porous template is coated with an inorganic dielectric material comprising an oxide, oxyhydroxide, oxyfluoride, nitride, or oxynitride of B, Si, Al, or Mg.

15. A method of making a radio frequency filter for a telecommunication system, the method comprising having a porous dielectric material made in accordance with the method of claim 1 provided on a substrate of the radio frequency filter.

16. A method of manufacturing substrate material, the method comprising
(a) providing a porous template,
(b) coating the porous template with an inorganic dielectric material or a pre-cursor to an inorganic dielectric material to form a coated porous template,
(c) annealing the coated porous template in air or oxygen to remove the template and to form a porous structure of dielectric material from the coating of inorganic dielectric material or precursor of an inorganic dielectric material, and
(d) depositing conductive material on at least one side of the porous structure of dielectric material to form RF components on the substrate material.

17. The method according to claim 16, wherein the porous template is a polymer template or a carbon skeleton template.

18. The method according to claim 17, wherein the porous template is a carbon skeleton template, and the carbon skeleton template is formed by pyrolyzing a polymer foam template.

19. The method according to claim 18, wherein the polymer foam template is a melamine foam template.

20. A substrate material, wherein the substrate material comprises
a support of porous dielectric material, which is formed by coating a porous template with the dielectric material or a precursor of dielectric material, and removing the porous template after coating,
optionally a sheet of biopolymer or synthetic polymer on at least on side of the support of porous dielectric material, and
a conductive material deposited on at least one side of the support of porous dielectric material.
